(19) United States
(12) Patent Application Publication
(10) Pub. No.: US 2013/0328061 A1
(43) Pub. Date: Dec. 12, 2013

(54) NORMALLY-OFF GALLIUM NITRIDE TRANSISTOR WITH INSULATING GATE AND METHOD OF MAKING THE SAME

(71) Applicants: Rongming Chu, Newbury Park, CA (US); Brian Hughes, Woodland Hills, CA (US); Andrea Corrion, Oak Park, CA (US); Shawn D. Burnham, Oxnard, CA (US); Karim S. Boutros, Moorpark, CA (US)

(72) Inventors: Rongming Chu, Newbury Park, CA (US); Brian Hughes, Woodland Hills, CA (US); Andrea Corrion, Oak Park, CA (US); Shawn D. Burnham, Oxnard, CA (US); Karim S. Boutros, Moorpark, CA (US)

(73) Assignee: HRL LABORATORIES, LLC., Malibu, CA (US)

(21) Appl. No.: 13/604,983

(22) Filed: Sep. 6, 2012

Related U.S. Application Data
(60) Provisional application No. 61/656,573, filed on Jun. 7, 2012.

(51) Int. Cl. H01L 29/778; H01L 29/24; H01L 21/335; H01L 29/20

(52) U.S. Cl. 257/77; 257/76; 257/194; 438/172; 257/E29.246; 257/E29.089; 257/E29.104; 257/E21.403

(57) ABSTRACT

A normally-off transistor includes a channel layer, an electron supply layer overlaying the channel layer, a source electrode and a drain electrode on the electron supply layer, an area in the electrode supply layer between the source electrode and the drain electrode treated with a fluoride based plasma followed by a chlorine based plasma treatment, a gate insulator overlaying the area, and a gate electrode overlaying the gate insulator.

### CROSS REFERENCE TO RELATED APPLICATIONS

The present application relates to and claims priority under 35 USC 120 to U.S. Provisional Patent Application No. 61/656,573, filed Jun. 7, 2012, which is hereby incorporated by reference in its entirety.

### FIELD

This disclosure relates to III-nitride transistors, such as gallium nitride (GaN) field effect transistors (FETs), and more particularly to normally-off III-nitride transistors.

### BACKGROUND

GaN FETs are solid state devices that have many uses including power switching applications. Some notable power switching applications include energy efficient vehicles, such as hybrid and fuel-cell vehicles, and high efficiency power conversion modules. Typically GaN FETs are made in a depletion-mode or “normally-on” configuration. For safety reasons, system designs may call for “normally-off” or enhancement-mode power switches. In this discussion, “normally-on” means that the transistor can conduct current without a voltage applied to the gate of the field effect transistor. “Normally-off” means that the transistor conducts essentially no or very little current unless a voltage is applied to the gate.

One prior art method to convert a normally-on device to a normally-off device has been described by Y. Cai, Y. G. Zhou, K. J. Chen, and K. M. Lau, “High-performance enhancement-mode AlGaN/GaN HEMTs using Fluoride-based plasma treatment,” IEEE Electron Dev. Lett. Vol. 26, no.7, pp. 435-437, July 2005. In Cai, after gate windows are opened by contact photolithography, the area under the gate window is treated with carbon tetrafluoride (CF₄) plasma in a reactive ion etching (RIE) system to produce a normally-off device. A disadvantage of the Cai device is that it has excessive gate leakage current, which limits the performance of the device.

What is needed is a normally-off device with very low gate leakage current, while also having a property of minimal threshold voltage hysteresis. The embodiments of the present disclosure answer these and other needs.

### SUMMARY

In a first embodiment disclosed herein, a normally-off transistor comprises a channel layer, an electron supply layer overlaying the channel layer, a source electrode and a drain electrode on the electron supply layer, an area in the electrode supply layer between the source electrode and the drain electrode treated with a fluoride based plasma followed by a chlorine based plasma treatment, a gate insulator overlaying the area, and a gate electrode overlaying the gate insulator.

In another embodiment disclosed herein, a method of making a normally-off transistor having a channel layer, an electron supply layer overlaying the channel layer, and a source electrode and a drain electrode on the electron supply layer, comprises treating an area in the electrode supply layer between the source electrode and the drain electrode with a fluoride based plasma, after the fluoride based plasma treatment, treating the area with a chlorine based plasma, forming a gate insulator overlaying the area, and forming a gate electrode on the gate insulator.

These and other features and advantages will become further apparent from the detailed description and accompanying figures that follow. In the figures and description, numerals indicate the various features, like numerals referring to like features throughout both the drawings and the description.

### BRIEF DESCRIPTION OF THE DRAWINGS

FIG. 1 shows a normally-off transistor in accordance with the present disclosure;

FIG. 2 shows a graph of the measured current-voltage (I-V) characteristics of a device fabricated in accordance with the present disclosure; and

FIG. 3 is a flow diagram of a method of making a normally-off transistor in accordance with the present disclosure.

### DETAILED DESCRIPTION

In the following description, numerous specific details are set forth to clearly describe various specific embodiments disclosed herein. One skilled in the art, however, will understand that the presently claimed invention may be practiced without all of the specific details discussed below. In other instances, well known features have not been described so as not to obscure the invention.

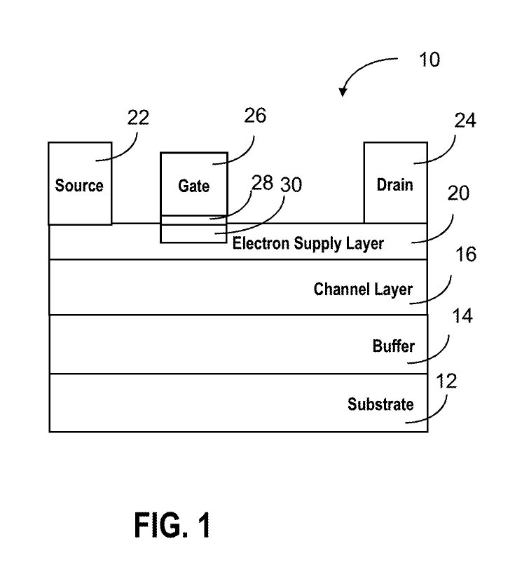

Referring now to FIG. 1, a III-nitride transistor 10 is shown in accordance with the present disclosure. The III in III-nitride refers to column III of the periodic table of elements, which includes aluminum (Al), gallium (Ga) and indium (In). The transistor 10 may include a substrate 12, buffer layer 14 overlaying the substrate 12, a channel layer 16 over the buffer layer 14, an electron supply layer 20 over the channel layer 16, and source electrode 22, drain electrode 24, and gate electrode 26, all of which are well known to persons skilled in the art.

The substrate 12 may be GaN, Si, SiC, Al₂O₃ or other suitable materials. The buffer layer 14 and the channel layer 16 may each be an III-nitride semiconductor. The electron supply layer 20 may be an III-nitride semiconductor with the bandgap greater than the channel layer 16. The source electrode 22 and the drain electrode 24 may be ohmic contacts.

A gate insulator 28 is placed below the gate electrode 26 in order to reduce gate leakage current. The gate insulator 28 may be an insulating dielectric film and may be aluminum oxide (Al₂O₃), silicon nitride (SiN), silicon oxide (SiO₂), aluminum nitride (AlN), hafnium oxide (HfO₂) or other suitable insulators. The gate insulator 28 may be deposited using atomic layer deposition (ALD).

During fabrication of the transistor, an area 30 of the electron supply layer 20 below the gate electrode is first treated with an fluoride (F) based plasma and then with a chlorine (Cl) based plasma. The plasma treatment may use a reactive ion etching (RIE) system. After treatment of area 30 with fluoride (F) based plasma followed by treatment with chlorine (Cl) based plasma treatment, the gate insulator 28 may be deposited over the area 30 and may be annealed in nitrogen (N₂) ambient for at least 1 minute. A gate electrode 26 is formed overlaying the gate insulator 28.

The fluoride (F) based plasma treatment reduces the electron concentration in the electron supply layer 20 under the gate electrode 26. However, the F-based plasma treatment can also cause surface trap states, which can trap electrons in the electron supply layer 20, and therefore reduce the performance of the transistor. The Chlorine (Cl) based plasma treatment removes surface trap states in the electron supply layer 20. The Cl-based plasma treatment also further reduces the electron concentration in the electron supply layer 20 under the gate electrode 26.

The result of the F-based plasma treatment followed by the Cl-based plasma treatment in area 30, and the gate insulator 28 between the gate electrode 26 and the electron supply layer 20, is a normally-off transistor 10 with a minimal threshold voltage hysteresis and very low gate leakage current.

Threshold voltage hysteresis refers to the difference between the gate bias voltage needed for switching the transistor 10 from on to off compared to the gate bias voltage needed for switching the transistor 10 from off to on. It is desirable in many applications that the threshold voltage hysteresis be minimal. In one device built according to the present disclosure a threshold voltage hysteresis of less than 0.2V was achieved. This result is significantly better than a typical threshold voltage hysteresis in the prior art which may be greater than 0.5V.

It is also desirable to have a very low gate leakage current. In one device built according to the present disclosure a gate leakage current of less than 100 nanoamps/millimeter was achieved.

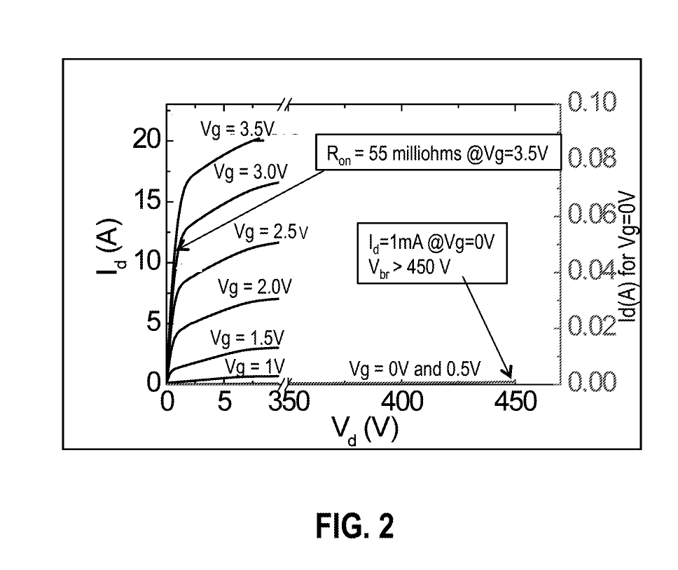

FIG. 2 shows a graph of the measured current-voltage (I-V) characteristics of a device fabricated in accordance with the present disclosure. The graph shows curves for the drain current (Id) versus drain voltage (Vd) for gate voltages (Vg) from 0.0V to 3.5V in 0.5V steps. The 0.0V and 0.5V gate voltage curves fall essentially on top of one another. The right axis of FIG. 2 shows Id for Vg=0V and indicates that the drain current is very low for Vg=0.0V, which is the gate voltage when the transistor is off.

As shown in FIG. 2, the on resistance Rₒₙ was measured to be 55 milliohms at Vg=3.5V. So when the transistor 10 is on, the resistance of the transistor is quite low. In addition, the device tested had at least a breakdown voltage (V_{br}) of 450 volts. Testing of the sample device was not extended above that voltage in order to not destroy the sample device; however, no breakdown was observed at 450 volts, and it is expected that devices made according to this disclosure will have quite acceptable breakdown voltages.

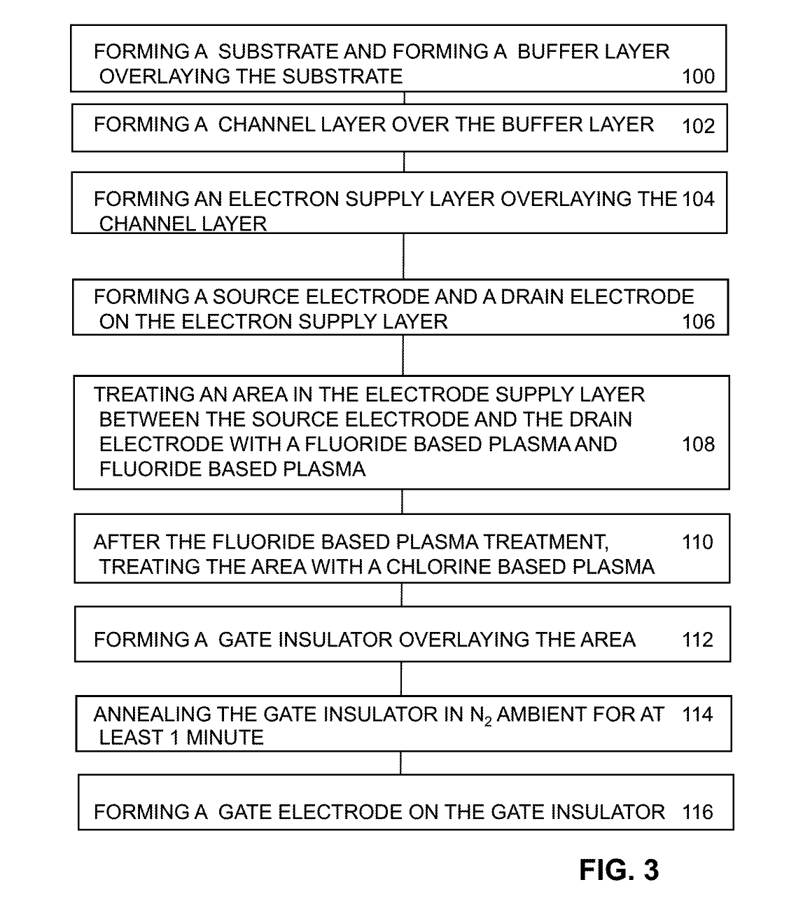

FIG. 3 is a flow diagram of a method of making a normally-off transistor. In step 100 a substrate is provided or formed and a buffer layer is formed overlaying the substrate. Then in step 102 a channel layer is formed over the buffer layer. In step 104 an electron supply layer is formed overlaying the channel layer. In step 106 a source electrode and a drain electrode are formed on the electron supply layer. In step 108 an area 30 in the electrode supply layer between the source electrode and the drain electrode is treated with a fluoride based plasma. Then, in step 110 after the fluoride based plasma treatment, the area 30 is treated with a chlorine based plasma. The fluoride based plasma and the chlorine based plasma treatment may be performed using reactive ion etching. In step 112 a gate insulator is formed overlaying the area. Next in step 114, the gate insulator is annealed in nitrogen (N₂) ambient for at least 1 minute. Then in step 116 a gate electrode is formed on the gate insulator. The gate insulator may be deposited using atomic layer deposition.

A person skilled in the art will understand that the order of the steps may be changed. For example, the substrate may be formed, then the buffer layer formed on the substrate, the channel layer formed on the buffer layer, the electron supply layer formed on the buffer layer, then the fluoride plasma treatment followed by the chlorine plasma treatment may be performed, then the gate insulator may be formed and finally the source, drain and gate electrodes formed.

Also a person skilled in the art will understand that the substrate, buffer layer, channel layer, electron supply layer, and source and drain electrodes may be provided and then the steps of fluoride plasma treatment followed by the chlorine plasma treatment may be performed, then the gate insulator may be formed and then the gate electrode formed.

Having now described the invention in accordance with the requirements of the patent statutes, those skilled in this art will understand how to make changes and modifications to the present invention to meet their specific requirements or conditions. Such changes and modifications may be made without departing from the scope and spirit of the invention as disclosed herein.

The foregoing Detailed Description of exemplary and preferred embodiments is presented for purposes of illustration and disclosure in accordance with the requirements of the law. It is not intended to be exhaustive nor to limit the invention to the precise form(s) described, but only to enable others skilled in the art to understand how the invention may be suited for a particular use or implementation. The possibility of modifications and variations will be apparent to practitioners skilled in the art. No limitation is intended by the description of exemplary embodiments which may have included tolerances, feature dimensions, specific operating conditions, engineering specifications, or the like, and which may vary between implementations or with changes to the state of the art, and no limitation should be implied therefrom. Applicant has made this disclosure with respect to the current state of the art, but also contemplates advancements and that adaptations in the future may take into consideration of those advancements, namely in accordance with the then current state of the art. It is intended that the scope of the invention be defined by the Claims as written and equivalents as applicable. Reference to a claim element in the singular is not intended to mean “one and only one” unless explicitly so stated. Moreover, no element, component, nor method or process step in this disclosure is intended to be dedicated to the public regardless of whether the element, component, or step is explicitly recited in the Claims. No claim element herein is to be construed under the provisions of 35 U.S.C. Sec. 112, sixth paragraph, unless the element is expressly recited using the phrase “means for . . . ” and no method or process step herein is to be construed under those provisions unless the step, or steps, are expressly recited using the phrase “comprising the step(s) of . . . ”

What is claimed is:

1. A normally-off transistor comprising:
a channel layer;
an electron supply layer overlaying the channel layer;
a source electrode and a drain electrode on the electron supply layer;
an area in the electrode supply layer between the source electrode and the drain electrode treated with a fluoride based plasma followed by a chlorine based plasma treatment;
a gate insulator overlaying the area; and
a gate electrode overlaying the gate insulator.

2. The transistor of claim 1 wherein:
the F-based plasma treatment reduces the electron concentration in the electron supply layer; and
the Cl-based plasma treatment removes surface trap states in the electron supply layer and further reduces the electron concentration in the electron supply layer.

3. The transistor of claim 1 wherein:
the area is treated with fluoride based plasma using reactive ion etching and then treated with a chlorine based plasma using reactive ion etching.

4. The transistor of claim 1 wherein:
the channel layer comprises a III-nitride semiconductor; and
the electron supply layer comprises a III-nitride semiconductor having a bandgap greater than the channel layer.

5. The transistor of claim 1 wherein the gate insulator comprises an insulating dielectric film, aluminum oxide (Al₂O₃), silicon nitride (SiN), silicon oxide (SiO₂), aluminum nitride (AlN), or hafnium oxide (HfO₂).

6. The transistor of claim 1 wherein the gate insulator is deposited by atomic layer deposition.

7. The transistor of claim 1 wherein the gate insulator is annealed in nitrogen (N₂) ambient for at least 1 minute.

8. The transistor of claim 1 wherein the transistor has a threshold voltage hysteresis of less than 0.2V.

9. The transistor of claim 1 wherein the transistor has a gate leakage current of less than 100 nanoamps/millimeter.

10. The transistor of claim 1 further comprising:
a substrate; and
a buffer layer overlaying the substrate and coupled to the channel layer.

11. The transistor of claim 10 wherein:
the substrate comprises GaN, Si, SiC, or Al₂O₃;
the buffer layer comprises a III-nitride semiconductor
the channel layer comprises a III-nitride semiconductor; and
the electron supply layer comprises a III-nitride semiconductor having a bandgap greater than the channel layer.

12. A method of making a normally-off transistor having a channel layer, an electron supply layer overlaying the channel layer, and a source electrode and a drain electrode on the electron supply layer, the method comprising:
treating an area in the electrode supply layer between the source electrode and the drain electrode with a fluoride based plasma;
after the fluoride based plasma treatment, treating the area with a chlorine based plasma;
forming a gate insulator overlaying the area; and
forming a gate electrode on the gate insulator.

13. The method of claim 12 wherein:
treating the area with the F-based plasma comprises reducing the electron concentration in the electron supply layer; and
treating the area with the Cl-based plasma comprises removing surface trap states in the electron supply layer and reducing the electron concentration in the electron supply layer.

14. The method of claim 12 wherein:
treating the area with the fluoride based plasma comprises reactive ion etching; and
treating the area with the chlorine based plasma comprises reactive ion etching.

15. The method of claim 12 wherein:
the channel layer comprises a III-nitride semiconductor; and
the electron supply layer comprises a III-nitride semiconductor having a bandgap greater than the channel layer.

16. The method of claim 12 wherein the gate insulator comprises an insulating dielectric film, aluminum oxide (Al₂O₃), silicon nitride (SiN), silicon oxide (SiO₂), aluminum nitride (AlN), or hafnium oxide (HfO₂).

17. The method of claim 12 wherein forming the gate insulator comprises depositing the gate insulator using atomic layer deposition.

18. The method of claim 12 further comprising annealing the gate insulator in nitrogen (N₂) ambient for at least 1 minute.

19. The method of claim 12 wherein the transistor has a threshold voltage hysteresis of less than 0.2V.

20. The method of claim 12 wherein the transistor has a gate leakage current of less than 100 nanoamps/millimeter.

21. The method of claim 12 further comprising:
forming a substrate; and
forming a buffer layer overlaying the substrate and coupled to the channel layer.

22. The method of claim 21 wherein:
the substrate comprises GaN, Si, SiC, or Al₂O₃;
the buffer layer comprises a III-nitride semiconductor
the channel layer comprises a III-nitride semiconductor; and
the electron supply layer comprises a III-nitride semiconductor having a bandgap greater than the channel layer.
